(19) United States
(12) Patent Application Publication
(10) Pub. No.: US 2006/0243993 A1
(43) Pub. Date: Nov. 2, 2006

(54) Light emitting diode chip and light emitting diode using the same

(75) Inventor: Tai-Cherng Yu, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/414,074

(22) Filed: Apr. 28, 2006

(30) Foreign Application Priority Data
Apr. 29, 2005 (TW) 94113916

(51) Int. Cl. H01L 33/00

(52) U.S. Cl. 257/95; 257/E33.006

(57) ABSTRACT

A light emitting diode chip includes a first electrode (13), a reflective layer (11) formed on the first electrode, a light emitting layer (12) formed on the reflective layer and a second electrode (14) arranged on the light emitting layer. The light emitting layer tapers in a direction from the second electrode to the first electrode. Therefore a cross section of the light emitting diode chip is trapezoidal in shape. A light emitting diode includes a base (20), a light emitting diode chip, a first terminal (30), a second terminal (40), a light-permeable cover (50). The present light emitting diode has high light emitting efficiency and low heat emission.

### BACKGROUND

1. Field of the Invention

The invention relates generally to light emitting diode, and more particularly, to a light emitting diode having high light emission efficiency by a novel light emitting diode chip thereof.

2. Discussion of Related Art

Light emitting diode (LED) is a semiconducting electronic device in which the injection of negative and positive charges leads to the emission of light from the device. LED is characterized in small size, high reliability, and high output, so LED is suitable for many kinds of devices, such as indoor or outdoor large displays, communication devices or electronic devices. Compared to conventional tungsten lamps, LED works without a filament, consume less power, and have shorter response times. Furthermore, LED gives better illumination, has a longer lifetime, does not contain harmful materials like mercury, has a smaller size, and lower power consumption. For all these reasons and more LED devices have become an increasingly popular light source.

LED is a simple sort of semiconductor device. Broadly speaking, a semiconductor is a material with a varying ability to conduct electrical current. In the case of LED, the conductor material is typically aluminum gallium arsenide (AlGaAs). In pure aluminum-gallium-arsenide, all of the atoms bond perfectly to their neighbors, leaving no free electrons to conduct electric current. In doped material, additional atoms change the balance, either adding free electrons or creating holes where electrons can go. The interaction between electrons and holes can generates photons. Photons are many small particle-like packets that have energy and momentum but no mass. LED is specially constructed to release a large number of photons outward.

LED usually includes a LED chip, two terminals and a glass cover. A typical chip includes a reflective layer and a light emitting layer formed on the reflective layer. A longitudinal section of the light emitting layer is generally rectangular. As such, before emitting from the light emitting layer, the photons are generally reflected many times inside the LED chips. This creates a great amount of heat in the light emitting layer. As a result, the semiconductor material itself absorb a lot of the heat energy. The heat generated by the LED becomes an important issue. Heat seriously affects the performance of LEDs. For example, the thermal effect will influence the wavelength of lights emitted from the LED, reduce the brightness of lights generated from the semiconductor device, and damage the LED device.

What is needed, therefore, is a light emitting diode which has high light emission efficiency.

### SUMMARY

The present invention provides a light emitting diode chip. In one embodiment, the light emitting diode chip includes a first electrode, a reflective layer formed on the first electrode, a light emitting layer formed on the reflective layer and a second electrode arranged on the light emitting layer. The light emitting layer tapers in thickness in a direction from the second electrode to the first electrode. Therefore a cross section of the light emitting diode chip is trapezoidal in shape.

In another embodiment, a light emitting diode is provided. The light emitting diode includes a base, the above-described light emitting diode chip, a first terminal, a second terminal, and a light-permeable cover. The light emitting diode chip is arranged on the base. The first terminal and the second terminal are electrically connected with the light emitting diode chip. The light-permeable cover encloses the light emitting diode chip therein.

Advantages and novel features of the present light emitting diode will become more apparent from the following detailed description of preferred embodiments when taken in conjunction with the accompanying drawings.

### BRIEF DESCRIPTION OF THE DRAWINGS

Many aspects of the present light emitting diode can be better understood with reference to the following drawings. The components in the drawings are not necessarily drawn to scale, the emphasis instead being placed upon clearly illustrating the principles of the present invention.

FIG. 1 is a schematic, cross-sectional view of a light emitting diode chip in accordance with a preferred embodiment of the present invention;

FIG. 2 is similar to FIG. 1, but showing light paths associated with the light emitting diode chip of FIG. 1; and

FIG. 3 is a schematic, cross-sectional view of a light emitting diode having a light emitting diode chip of FIG. 1, in accordance with another preferred embodiment of the present invention.

Corresponding reference characters indicate corresponding parts throughout the several views. The exemplifications set out herein illustrate at least one preferred embodiment of the present light emitting diode chip and the light emitting diode using the same, in one form, and such exemplifications are not to be construed as limiting the scope of the invention in any manner.

### DETAILED DESCRIPTION OF PREFERRED EMBODIMENTS

Reference will now be made to the drawings to describe embodiments of the present light emitting diode chip and the light emitting diode using the same, in detail.

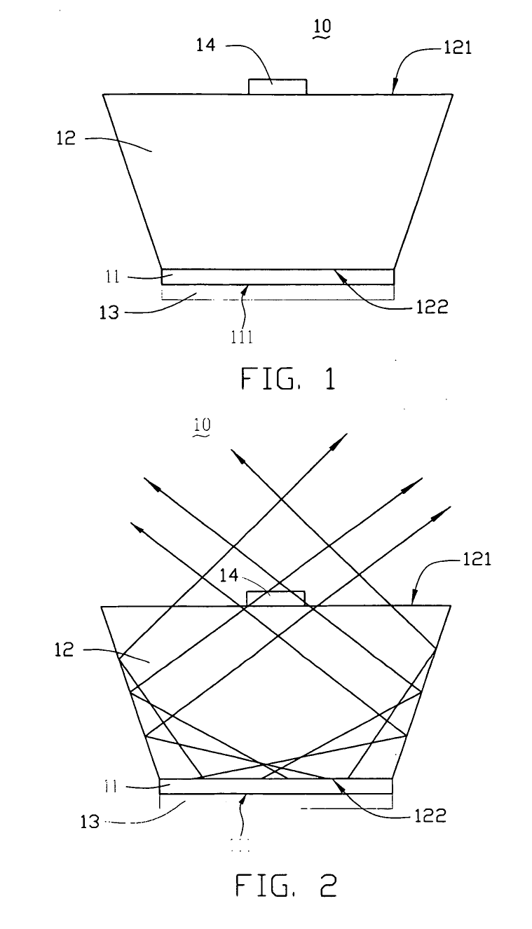

Referring to FIG. 1, a light emitting diode chip 10 according to an embodiment of the present invention includes a first electrode 13, a reflective layer 11, a light emitting layer 12 formed on the reflective layer 11 and a second electrode 14. The light emitting layer 12 has a top surface 121 where the second electrode 14 is mounted thereon. The reflective layer 11 has a bottom surface 111, and the first electrode 13 is attached thereto. The light emitting layer 12 tapers in a direction from the second electrode 14 to the first electrode 13. Therefore a cross section of the light emitting diode chip 10 is trapezoidal in shape as shown as FIG. 1.

The reflective layer 11 is comprised of n-type Gallium Arsenide (GaAs). The light emitting layer 12 is comprised of a material selected from the group consisting of Indium Gallium Aluminum Phosphide (InGaAIP) and Gallium Phosphide (GaP). The light emitting layer 12 includes a number of quantum dots for emitting light. The first electrode 13 is a n-type semiconductor. The second electrode 14 is a p-type semiconductor. The second electrode 14 functions as an electrode pad for bonding with a metal conductor (not shown). The light emitting diode chip 11 is produced by forming a wafer including the respective layers 11, 12 and the electrodes 13, 14, and slicing the wafer into separate chips.

Referring to FIG. 2, the light emitted is reflected inside the of the light emitting diode chip 10. Because the top surface 121 of the light emitting diode chip 11 is larger than the bottom surface 111, more of the emitted light is propagated to the outside of the light emitting diode chip 10 than in conventional light emitting diode chips whose shapes are square. Thus the present invention can reduce the heat generated inside the light emitting diode chip thereby improving the light emission efficiency.

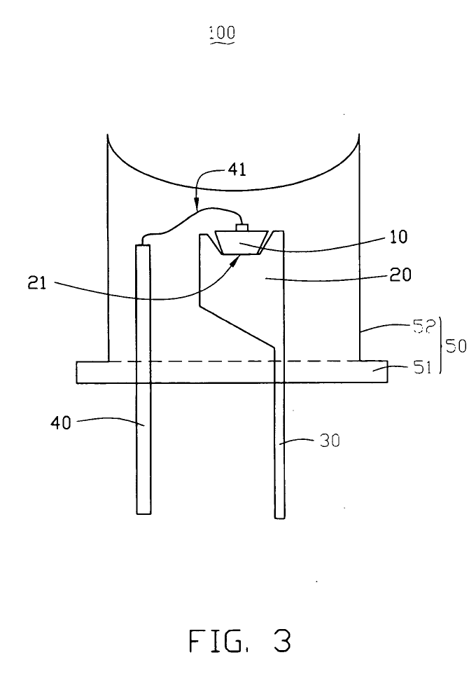

Referring to FIG. 3, a light emitting assembly, i.e. light emitting diode 100 according to an embodiment of the present invention includes a base 20, the above-described light emitting diode chip 10, a first terminal 30, a second terminal 40, and a light-permeable cover 50. The base 20 defines a reflective cup 21 and the first terminal 30 is connected with the base 21. The light emitting diode chip 10 is received and fixed in the reflective cup 21 and is connected to the second external terminal 40 via a conductor wire 41. A bottom plate of the light-permeable cover 51 is used to seal the base 20, the light emitting chip 10, the conductor 41 and portions of the first 30 and second 40 terminals. The first 30 and second 40 terminals extend beyond the bottom plate 51. A cover lens of the light-permeable cover 52 is made of glass and positioned on the bottom plate 50 at a position corresponding to the light emitting diode chip 10. The cover lens 52 is concave and its position spatially corresponds to that of the light emitting diode chip 10 thus eliminating spotlight points from the light emitting diode chip 10.

In the above embodiment, a single light emitting diode chip 10 is provided in the light emitting assembly 100. However, it is also possible to mount a number of light emitting diode chips 10 in the light emitting assembly 100 for back-lighting a liquid crystal display or a number of key switches.

The light emitting diode chip 10 and the light emitting assembly 100 using the same can be used as a light source in various portable electronic equipment powered by batteries such as a mobile phone, a beeper, a video camera working integrally with a videotape recorder and the like. Thus, the power consumption lighting is advantageously reduced due to the higher emission efficiency of the light emitting diode chip 10, thereby enabling greater use of the above mentioned portable devices, particularly when used in a mobile phone. With the present light emitting assembly it is possible for a small forward current of about 2-5 mA to give sufficient luminosity to the light a liquid crystal display or a set of key switches.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

I claim:

1. A light emitting diode chip comprising:
a first electrode;
a reflective layer formed on the first electrode;
a light emitting layer formed on the reflective layer; and
a second electrode arranged on the light emitting layer, wherein the light emitting layer tapers in a direction from the second electrode to the first electrode.

2. The light emitting diode chip as claimed in claim 1, wherein a cross section of the light emitting diode chip is a trapezoidal in shape.

3. The light emitting diode chip as claimed in claim 1, wherein the light emitting layer is comprised of a material selected from the group consisting of indium gallium aluminum phosphide (InGaAlP) and gallium phosphide (GaP).

4. The light emitting diode chip as claimed in claim 1, wherein the reflective layer is comprised of n-type gallium arsenide (GaAs).

5. The light emitting diode chip as claimed in claim 1, wherein the light emitting layer comprises a plurality of quantum dots for emitting light.

6. A light emitting diode comprising:
a base;
a light emitting diode chip arranged on the base, the light emitting diode chip comprising a first electrode, a reflective layer formed on the first electrode, a light emitting layer formed on the reflective layer; and a second electrode arranged on the light emitting layer; wherein thickness of the light emitting layer tapers in a direction from the second electrode to the first electrode;
a first terminal electrically connected with the first electrode;
a second terminal electrically connected to the second electrode; and
a light-permeable cover enclosing the light emitting diode chip therein.

7. The light emitting diode as claimed in claim 6, wherein a cross section of the light emitting diode chip is a trapezoidal in shape.

8. The light emitting diode as claimed in claim 6, wherein the light emitting layer is comprised of a material selected from the group consisting of InGaAlP and GaP.

9. The light emitting diode as claimed in claim 6, wherein the reflective layer is comprised of n-type GaAs.

10. The light emitting diode as claimed in claim 6, wherein the cover comprises a concave lens portion spatially corresponding to the light emitting diode chip.
